(19) United States
(12) Patent Application Publication
(10) Pub. No.: US 2002/0173169 A1
(43) Pub. Date: Nov. 21, 2002

(54) Two-step flourinated-borophosophosilicate glass deposition process

(75) Inventors: Francimar Campana, Milpitas, CA (US); Li-Qun Xia, San Jose, CA (US); Ellie Yieh, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/832,756

(22) Filed: Apr. 10, 2001

(51) Int. Cl. H01L 21/469; H01L 21/31

(52) U.S. Cl. 438/784

(57) ABSTRACT

A method for depositing a layer over a substrate includes depositing a first halogen-doped borophosphosilicate glass (BPSG) layer over said substrate at a first pressure level. A second halogen-doped BPSG layer is deposited over said first layer at a second pressure level, wherein said first pressure level is higher than said second pressure level.

### BACKGROUND OF THE INVENTION

The present invention relates to the formation of a borophosphosilicate glass (“BPSG”) layer during the fabrication of integrated circuits on semiconductor wafers. More particularly, the present invention relates to a method for improving the reflow characteristics of a BPSG film enabling the film to fill gaps having higher aspect ratios and smaller widths while meeting the thermal budget requirements of modem day manufacturing processes.

Borophosphosilicate glass (“BPSG”) has found wide use in the semiconductor industry as a separation layer between the polysilicon gate/interconnect layer and the first metal layer of MOS transistors. Such a separation layer is often referred to as a premetal dielectric (PMD) layer because it is deposited before any of the metal layers in a multilevel metal structure and is used to electrically isolate portions of the first deposited metal layer from the semiconductor substrate.

In addition to having a low dielectric constant, low stress and good adhesion properties, it is important for PMD layers to have good planarization and gap-fill characteristics. BPSG deposition methods have been developed to meet these characteristics and often include planarizing the layer by heating the layer above its reflow temperature so that it flows as a liquid. The reflow process enables the BPSG to better fill high-aspect ratio, small-width trenches and results in a flat upper surface upon cooling. The heating necessary to reflow a BPSG layer can be achieved using either a rapid thermal pulse (RTP) method or a conventional furnace in either a dry (e.g., N₂ or O₂) or wet (e.g., steam H₂/O₂) ambient. These processes are generally considered to be somewhat equivalent and thus interchangeable for many applications. If any particular benefits are attributable to one process over the others, however, persons of skill in the art generally believe that annealing a BPSG layer in a conventional furnace having a wet (steam) ambient provides better gap-fill properties than using RTP methods and that dry conventional furnace anneals are basically equivalent to RTP methods in terms of gap-fill characteristics.

Standard BPSG films are formed by introducing a phosphorus-containing source and a boron-containing source into a processing chamber along with the silicon- and oxygen-containing sources normally required to form a silicon oxide layer. Examples of phosphorus-containing sources include triethylphosphate (TEPO), triethylphosphite (TEPᵢ), trimethylphosphate (TMPO), trimethylphosphite (TMPᵢ), and similar compounds. Examples of boron-containing sources include triethylborate (TEB), trimethylborate (TMB), and similar compounds.

As semiconductor design has advanced, the feature size of the semiconductor devices has dramatically decreased. Many integrated circuits (ICs) now have features, such as traces or trenches that are significantly less than a micron across. While the reduction in feature size has allowed higher device density, more complex circuits, lower operating power consumption, and lower cost, the smaller geometry has also given rise to new problems or has resurrected problems that were once solved for larger geometry.

One example of a manufacturing challenge presented by submicron devices is the ability to completely fill a narrow trench in a void-free manner while keeping the thermal budget of the trench-filling process at a minimum. For example, in order to meet the manufacturing requirements of 0.18 micron geometry devices and below, a BPSG layer may be required to fill 0.1-micron-wide gaps and narrower having an aspect ratio (the ratio of depth to width) of up to 6:1. At the same time, these manufacturing requirements require that the thermal budget of the BPSG deposition and reflow step be kept to a minimum.

One method that manufacturers have developed in efforts to meet these and/or similar requirements is the addition of fluorine or a similar halogen element to the BPSG film. Such fluorine-doped BPSG films are often referred to as “fluorinated-BPSG” or “FBPSG.” Fluorine is believed to lower the viscosity of the BPSG film so that it reflows more easily during the reflow step. In this manner, the addition of fluorine can be used to improve the gap-fill and planarization of BPSG layers when deposited and reflowed at a given temperature. Alternatively, the addition of fluorine can be used to reduce the reflow temperature of the BPSG film while retaining gap-fill and planarization characteristics of a BPSG film reflowed at a higher temperature. U.S. Pat. No. 5,633,211 illustrates one example of a method used to deposit a FBPSG layer.

### SUMMARY OF THE INVENTION

The present invention relates to the formation of a borophosphosilicate glass layer during the fabrication of semiconductor devices. In one embodiment, a method for depositing a layer over a substrate includes depositing a first halogen-doped borophosphosilicate glass (BPSG) layer over said substrate at a first pressure level. A second halogen-doped BPSG layer is deposited over said first layer at a second pressure level, wherein said first pressure level is higher than said second pressure level.

This and other embodiments of the present invention along with many of its advantages and features are described in more detail in conjunction with the text below and the attached figures.

### BRIEF DESCRIPTION OF THE DRAWINGS

FIG. 1A is a simplified cross-sectional view of a silicon substrate, which has an exemplary integrated circuit partially formed thereon, over which a BPSG layer deposited and planarized according to the method of the present invention may be formed;

FIG. 1B is a simplified cross-sectional view of the silicon substrate shown in FIG. 1A after the BPSG layer has been planarized;

FIG. 2A is a sketch of an SEM photograph showing a BPSG layer 40 after the layer has been reflowed;

FIG. 2B is a sketch of an SEM photograph showing a BPSG layer 60 that includes voids 68 after the layer has been reflowed using prior art reflow methods;

FIG. 3 is a flowchart illustrating the steps of an embodiment of the method of the present invention;

FIG. 4A is a sketch of an SEM photograph showing FBPSG layers 204 and 206 after they have been deposited on a substrate 200 according to an embodiment of the present invention; and

FIG. 4B is a sketch of the SEM photograph of FIG. 4A after the FBPSG layers 204 and 206 have been reflowed according to an embodiment of the present invention.

### DESCRIPTION OF THE SPECIFIC EMBODIMENTS

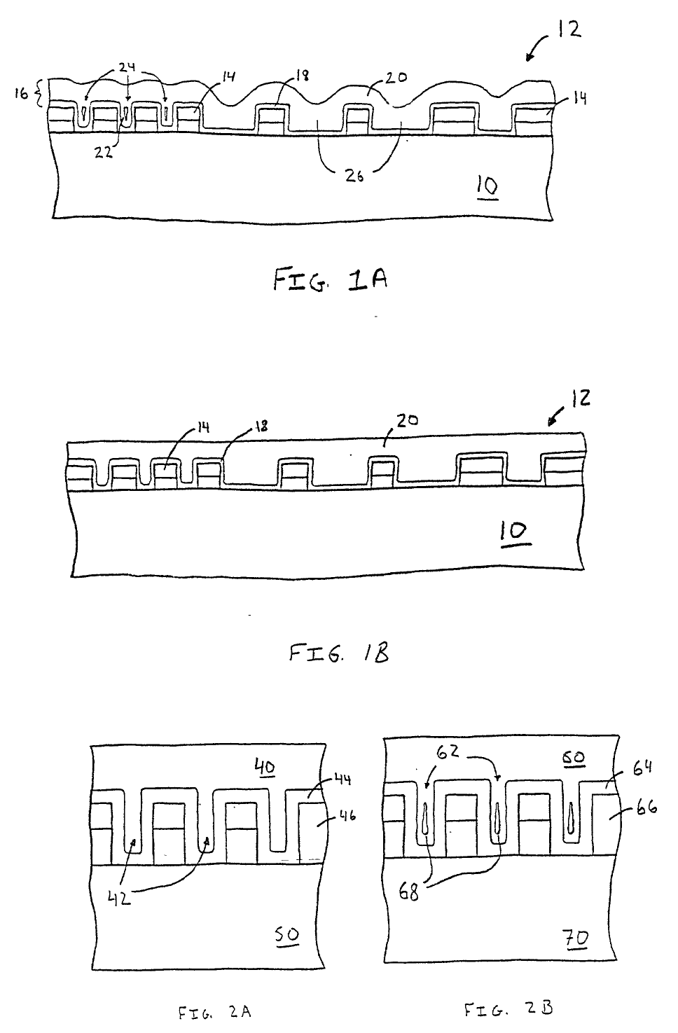

FIG. 1A is a simplified cross-sectional view of a silicon substrate 10 having an exemplary integrated circuit 12 partially formed thereon. As shown in FIG. 1A, integrated circuit 12 includes a plurality of raised structures 14, such as polycide conductive lines and polycide gate structures, and an insulation layer 16 deposited over the raised structures. Insulation layer 16 includes a lining layer 18 and a BPSG gap-fill layer 20. Lining layer 18 separates gap-fill layer 20 from the underlying substrate and raised features and helps prevent moisture and ionic contamination from penetrating into the substrate and raised features.

Lining layer 18 is typically an undoped silicon oxide layer or a silicon nitride layer. One common method of forming an undoped silicon oxide layer 18 is from a plasma enhanced chemical vapor deposition (CVD) process that employs tetraethoxysilane (TEOS) and oxygen as precursor gases. A common method of forming a silicon nitride layer 18 is from a low pressure CVD process that uses silane and nitrogen as precursor gases. FIG. 1A shows BPSG layer 20 prior to the planarization or reflow of the layer. Also shown in FIG. 1A are voids 22 that may form in BPSG layer 20 during its deposition if the aspect ratio (ratio of the height to width) of a gap between any two adjacent raised structures 14 into which the BPSG layer is deposited is sufficiently high. As is common in the manufacture of actual integrated circuits, FIG. 1A shows voids 22 forming in high aspect ratio, narrow-width gaps 24 and not in low aspect ratio, wide-width gaps 26.

FIG. 1B shows integrated circuit 12 after BPSG layer 20 has been reflowed. As evident in FIG. 1B, the reflow process results in the flattening or planarization of layer 20 and, ideally, the filling of voids 22. Whether or not voids 22 are completely filled as is shown in FIG. 1B depends on the temperature, length and type of reflow process used, the boron and phosphorus concentrations of the BPSG layer, whether or not BPSG layer 20 is further doped with a halogen element such as fluorine, and the shape of the voids, among other factors. For example, as is known to those of skill in the art, the glass transition temperature (reflow temperature) of a given BPSG layer 20 depends in part on the boron and phosphorus dopant concentrations of the layer. Standard BPSG films typically have between a 2-6 weight percent (wt. %) boron concentration, a 2-9 wt. % phosphorus concentration and a combined dopant concentration (boron and phosphorus) of about 11 wt. % or less. Generally speaking, increasing the boron concentration of the BPSG layer reduces the reflow temperature of the layer. At boron concentration levels of higher than 6 wt. %, however, a given BPSG layer is likely to be susceptible to moisture and diffusion problems.

FIGS. 1A and 1B are generic structures and can represent embodiments of the present invention as well as embodiments of the prior art.

As described in the Background of the Invention section above, one known method of improving the reflow characteristics of layer 20, including the ability of the reflow process to eliminate any voids 22 formed in the film, is to incorporate a halogen element into the BPSG layer during the film deposition process. The most common halogen element to include in the BPSG layer is fluorine. Fluorine can be incorporated into a BPSG film by adding a fluorine-containing source gas such as vaporized triethylfluorosilane (TEFS) to the BPSG process gas.

The present inventors have discovered, however, that the physical properties of lining layer 18 and the type of reflow process used to planarize BPSG layer 20 can greatly affect the reflow characteristics of a BPSG layer when the layer incorporates fluorine or another halogen element to improve its reflow characteristics. FIG. 2A is a sketch of an SEM photo showing the 3×8 FBPSG layer 40 (3 wt. % boron, 8 wt. % phosphorus) after the reflow process. The reflow was performed for 30 minute at 800° C. in an N₂ ambient environment. As shown in FIG. 2A, the deposited FBPSG layer was able to fill narrow-width gaps 42 having aspect ratios of about 4:1 without the formation of voids. Also shown in FIG. 2A is an LP nitride layer 44 deposited over raised structures 46 formed on a substrate 50.

The same deposition and reflow processes, however, could not adequately fill the same size gap when the FBPSG layer was deposited over a plasma-enhanced tetraethoxysilane (PETEOS) oxide layer. FIG. 2B is a sketch of an SEM photo showing the resulting structure. A substrate 70 has thereon an FBPSG layer 60, PETEOS oxide layer 64, narrow-width 4:1 aspect ratio gaps 62 and raised structures 66. Unlike the process described above, voids 68 remained after the reflow step under this process.

In analyzing the above and other test results, the inventors were able to conclude that the gap-fill characteristics of an FBPSG layer depended at least in part on the type of layer the FBPSG film was deposited over when the layer was reflowed using a conventional furnace annealing process. The inventors then performed a series of experiments reflowing the layer using a rapid thermal pulse (RTP) method. As mentioned in the Background of the Invention section above, RTP and conventional furnace anneal processes are generally considered to be somewhat equivalent by those of skill in the art. If any particular benefits are attributed to one process over the other, however, persons of skill in the art generally believe that annealing a BPSG layer in a conventional furnace having a wet (steam) ambient provides better gap-fill properties than using RTP methods.

The present inventors discovered, however, much to their surprise that annealing an FBPSG layer deposited over a PETEOS silicon oxide layer with an RTP process resulted in a significant improvement in the gap-fill characteristics of the FBPSG layer. For example, when the 3×8 FBPSG layer deposited over a PETEOS oxide layer discussed above with respect to FIG. 2B was annealed at 950° C. for 20 seconds in an N₂ ambient using an RTP process, the layer was able to completely fill the gaps 62 without the formation of any voids 68 between the gaps. Furthermore, the degree of planarization of the layer was essentially the same as that of the layers reflowed using the longer, conventional anneal process (30 minutes, 800° C).

While not being restricted by any particular theory of operation, the inventors believe that the unexpected superior results that were achieved using an RTP anneal process to reflow the FBPSG layer, instead of using a conventional furnace anneal, are a result of the high mobility of fluorine within the layer. The inventors believe that in the experiments in which an FBPSG layer was deposited over a PETEOS silicon oxide layer, the fluorine from the FBPSG layer rapidly diffused from the layer into the PETEOS layer and into the substrate beneath the PETEOS layer. It is further believed that the diffusion of fluorine atoms in this manner likely occurs during the early stages of the anneal process, e.g., the first 5-10 seconds. Thus, for much of the anneal process the FBPSG layer is without the benefit of fluorine atoms that have been shown to increase the viscosity of the layer during the reflow process and hence improve the layer reflow characteristics. Deprived of this benefit for a significant portion of the reflow process, the reflow process is unable to fill high aspect ratio, narrow-width gaps in a manner substantially free of voids that could otherwise be filled.

The LP nitride layer is significantly more dense (approximately 2.8-3.1 g/cm³) than the PETEOS layer (approximately 2.2 g/cm³). Thus, the inventors believe that when the FBPSG layer deposited over the LP nitride layer was annealed in a conventional furnace, the LP nitride layer acted as a diffusion barrier slowing the diffusion of fluorine atoms into the nitride layer and substrate.

Further tests indicated that the use of higher reflow temperatures during a conventional furnace anneal resulted in worse, not better, reflow characteristics of an FBPSG layer deposited over an LP nitride layer. This is contrary to what would normally be expected as, other factors being equal, higher reflow temperatures generally result in better gap-fill and planarization characteristics. The inventors believe, however, that at higher reflow temperatures, the fluorine diffuses through the nitride layer more quickly than at lower reflow temperatures. Thus, FBPSG layers reflowed at higher temperatures in a conventional furnace become fluorine deprived, and thereby loose the benefits fluorine imparts to the FBPSG film, sooner than those reflowed at lower temperatures. A more detailed description of a method for depositing and planarizing fluorinated BPSG film is set forth in U.S. Ser. No. 09/262,782, entitled “An Improved Method for Depositing and Planarizing Fluorinated BPSG Films,” which was filed on Mar. 4, 1999, and assigned to the assignee of the present application, which is hereby incorporated by reference in its entirety.

In addition to the above studies, the present inventors have conducted a series of experiments to determine the effects of varying process parameters on deposition of BPSG films. A more detailed description of these experiments and discoveries is set forth in U.S. Ser. No. 09/076,170, entitled “A Two-Step Borophosphosilicate Glass Deposition Process and Related Devices and Apparatus,” which was filed on May 5, 1998, and assigned to the assignee of the present application, and which is hereby incorporated by reference in its entirety. These experiments showed that film conformity improves with the increase of chamber pressure. However, this improvement in film conformity comes at the cost of reduced deposition rate. That is, if the pressure is set too high in an effort to achieve film conformity optimization, then the deposition rate drops to an undesirably low level.

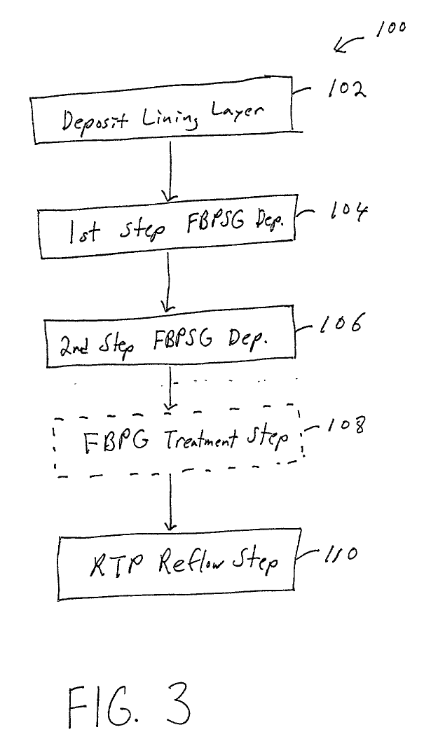

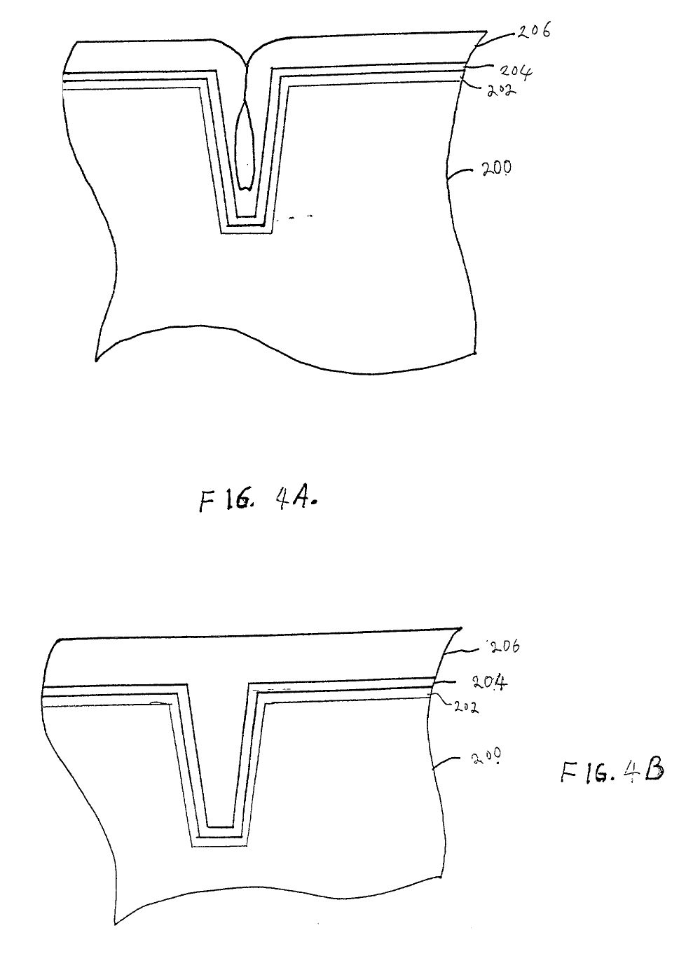

Accordingly, one FBPSG-film-deposition process recipe devised by the inventors involved depositing the film at a particular chamber pressure, e.g., at 200 Torr, that is optimized for both film conformity and relatively high deposition rate. The inventor, however, found that this one-step deposition method had difficulty filling 0.08-micron-wide gaps having an aspect ratio of about 6:1. Since the feature size of the semiconductor devices is decreasing at an accelerated pace, the inventors pressed on to develop a deposition method which would allow even better gap filling capability than the one provided above. Method or process 100 (FIG. 3) describes an embodiment of the improved deposition method discovered by the inventors.

Referring to FIGS. 3-4B, process 100 for depositing and planarizing FBPSG film incorporates a two-step deposition method for depositing a fluorine or other halogen-doped BPSG layers. Generally, the first deposition step is optimized for film conformity, and the second step is optimized for deposition rate.

Process 100 involves depositing a lining layer 202, such as an undoped silicon oxide or silicon nitride layer over a substrate 200 (step 102). The lining layer may be a silicon oxide layer, silicon nitride layer, or the like. However, when an FBPSG layer is reflowed in a conventional furnace, the lining layer preferably is a silicon nitride layer or similarly dense layer to prevent the diffusion of fluorine atoms into the lining layer and into the substrate beneath. In addition, the furnace anneal is preferably performed at a relatively low reflow temperature of about 750° C. or less. Using lower reflow temperatures results in either a longer reflow process or a film that is not fully planarized, or both. Therefore, the preferred reflow method is to perform an RTP reflow at a temperature over 900° C., as explained subsequently.

Referring to FIGS. 3 and 4A, a first FBPSG layer 204 is deposited on lining layer 202 (step 104) in a relatively high chamber pressure, preferably between about 300 Torr to about 400 Torr. Step 104 is performed for about 26 seconds so that the first layer is about 600-700 Å thick. The first layer has a relatively low deposition rate of about 1000 to 2000 Å/min, which is undesirable since the low deposition rate reduces throughput. However, the first layer has good film conformity that is important in filling small gaps. The first layer has between about 0.5 to 3.0 wt. % fluorine. Generally speaking, the more fluorine incorporated into the film, the better the film's reflow properties. Higher fluorine concentrations, however, also result in film stability and moisture resistance problems.

Once the first, conformal layer has been deposited, a second FBPSG layer 206 is deposited thereon at a lower chamber pressure, preferably between about 150 Torr to about 200 Torr (step 106). Step 106 is performed for about 126 seconds so that the second layer is about 9000 Å thick. The second layer has a relatively higher deposition rate of about 4000 to 5000 Å. The second layer is directed to increasing the deposition rate. As with the first layer, the second FBPSG layer also has between about 0.5 to 3.0 wt. % fluorine.

Regarding step 104, the present inventors unexpectedly discovered that it is important to keep the pressure no more than about 400 Torr when depositing first layer 204 for optimal film conformity. The inventors expected the optimal pressure for film conformity to be much higher than 400 Torr since their previous experiences with BPSG film deposition techniques showed that the deposition conformity improves with an increase in pressure. The inventors discovered that the improvement in the eventual film conformity unexpectedly leveled off at about 400 Torr. After extensive investigation, the inventors discovered that the leveling off effect results because fluorine concentration in the first FBPSG layer decreases with the pressure increase, thereby diminishing the reflow characteristics of the deposited film. While not being restricted to any particular theory, the inventors believe that this decrease in fluorine concentration occurs with the higher pressure because of increased gas phase reactions at higher pressure may result in agglomeration of TEB, TEPO, and TEFS. Therefore, the improvement in film conformity resulting from increasing the pressure is offset by fluorine deprivation resulting from the pressure increase.

In addition, the inventors discovered that substrates with FBPSG layers which were formed at high pressure were producing contact holes with undercuts (not shown). Contact holes with undercuts are undesirable since they may short the device. The inventors discovered that the undercuts are associated with the pressure increase. The FBPSG-layer deposited at high pressure causes boron atoms to migrate toward the interface between the FBPSG layer and the substrate, so that a significant concentration of boron atoms is formed at the interface. The boron atoms concentrated at the interface react with the solution, such as a BHF solution, into which the substrate is dipped after the contact etch. The resulting chemical reaction causes the undercuts to form in the contact holes. The inventors conducted a series of experiments to determine the acceptable pressure ranges for depositing the first FBPSG layer, which would avoid a significant boron migration to the interface. They found that an FBPSG layer deposited at 300 Torr produced no noticeable concentration of boron at the interface. Upon further investigation, the inventors found that an FBPSG layer deposited at about 400 Torr had some boron concentration at the interface but the concentration level was low enough to be acceptable for the purposes of process 100. Generally, the pressure should be adjusted so that boron concentration at the interface is no greater than 2 wt. % of the boron concentration in the bulk FBPSG layer, or preferably, no more than about 1 wt. %, or more preferably no more than about 0.5 wt. %. Therefore, the first FBPSG layer preferably is deposited at a chamber pressure of between 300-400 Torr for optimal film conformity without forming undesirable undercuts in the contact holes. In other implementations, the first FBPSG layer may be deposited at a chamber pressure of between 200-400 Torr for optimal film conformity without forming undesirable undercuts in the contact holes.

In preferred embodiments, both the first and second FBPSG layers are preferably deposited in a cold-walled CVD deposition chamber rather than in a hot-walled LPCVD chamber. One particular example of such a cold-walled CVD chamber is the Gigafill™ chamber manufactured by Applied Materials. A detailed description of such a chamber is set forth in U.S. Ser. No. 08/748,883 entitled “Systems and Methods for High Temperature Processing Semiconductor Wafers” issued to Zhao et al. The 08/748,883 application was filed on Nov. 13, 1996, is assigned to Applied Materials, the assignee of the present invention, and is hereby incorporated by reference in its entirety.

Deposition of the film in a cold-walled chamber, such as the Gigafill™ chamber, allows for improved wafer temperature uniformity (the wafer is heated directly on a ceramic heater), minimizes unwanted gas phase reactions (resulting in fewer particles) and allows the use of higher deposition pressures (greater than 10 torr). Higher pressures allow for higher gas flow rates and more uniform gas flows, higher film deposition rates at lower deposition temperatures, and better film quality.

In the currently preferred embodiment, the FBPSG layers are deposited from a process gas of TEOS, TEFS, ozone, TEB and TEPO using a sub-atmospheric pressure chemical vapor deposition process. As would be understood by a person of ordinary skill in the art, the actual flow rates and other processing conditions will vary depending on the type and volume of the deposition chamber used and the desired film properties. In one embodiment in which FBPSG layers are deposited in a Gigafill™ chamber outfitted for 8-inch wafers, deposition of the first layer occurs at 300 Torr and 480° C. The process gas includes 17 wt. % O₃ (5000 sccm) and 6000 sccm of He acting as a carrier gas for 350 milligram per minute (mgm) of a mixture of 50% TEOS and 50% TEFS, 120 mgm TEB and 70 mgm TEPO. Each of the TEOS/TEFS, TEB and TEPO are vaporized in a liquid injection system and then mixed with the helium carrier gas.

Deposition of the second layer occurs at 200 Torr and 480° C. The process gas includes 17 wt. % O₃ (5000 sccm) and 6000 sccm of He acting as a carrier gas for 800 mgm of a mixture of 50% TEOS and 50% TEFS, 400 mgm TEB and 70 mgm TEPO.

The present inventors have found that the inclusion of both TEOS and TEFS into the process gas results in improved film deposition qualities. Higher TEOS flow rates generally result in improvements to the FBPSG film's deposition rate, etch rate, density and stability. Higher TEFS flow rates, on the other hand, generally improve the film's reflow characteristics and thus produce better gap-fill properties. A ratio of about 50/50 TEOS and TEFS is currently thought to be an ideal balance between the two as the change in film properties is not directly proportional to the mixing concentration.

Table 1 below provides a process recipe for depositing the first and second layers according to one embodiment of the present invention.

TABLE 1
Process Recipe

| | 1st Step FBPSG Deposition | 2nd Step FBPSG Deposition |
|---|---|---|
| Pressure | 200-400 Torr, preferably 300 | 100-300 Torr, preferably 150-200 Torr |
| | Torr | |
| Pedestal Temp. | 450-600° C. | 450-600° C. |
| Ozone | 6 wt.% at 2,500 sccm to 17 wt.% | 6 wt.% at 2,500 sccm to 17 wt.% at |
| | at 5,000 sccm | 5,000 sccm |
| TEOS/TEFS | 100-400 mgm at about 50% | 400-1000 mgm at about 50% TEOS |
| | TEOS and 50% TEFS, | and 50% TEFS, preferably 750-850 |
| | preferably 250-350 mgm at | mgm at about 50% TEOS and 50% |
| | about 50% TEOS and 50% | TEFS |
| | TEFS | |
| TEB | 90-150 mgm, preferably 120 | 375-450 mgm, preferably 400 mgm |
| | mgm | |
| TEPO | 50-100 mgm, preferably 70 mgm | 50-100 mgm, preferably 70 mgm |
| Deposition | 1600 Å/min | 4300 Å/min |
| Rate | | |

After the first and second layers of FBPSG film have been deposited, they are reflowed using an RTP reflow step (step 110). FIG. 4B shows a schematic cross section of substrate 200 after the RTP reflow step. RTP reflow step 110 generally heats the layer to a temperature over 900° C. for between about 20-90 seconds, and can be done in commercially available RTP furnaces such as the Centura™ RTP manufactured by Applied Materials, assignee of the present invention. Such commercially available RTP furnaces generally allow rates of change of wafer temperature as high as ±50-100° C./sec. A more detailed description of one RTP furnace that can be used to reflow the FBPSG layer in step 120 is set forth in U.S. Pat. No. 5,155,336 entitled “Rapid Thermal Heating Apparatus and Method” issued to Gronet et al. The 5,155,336 patent is assigned to Applied Materials, the assignee of the present invention, and is hereby incorporated by reference in its entirety.

The use of RTP reflow step 110 achieves film reflow in a rapid manner so that most of the fluorine atoms incorporated into the FBPSG layers do not have time to diffuse from the layer. Thus, the FBPSG layers receive the full benefit of fluorine incorporation. This, in turn, allows the RTP-reflowed FBPSG layers to achieve superior gap-fill results as compared to reflowing the FBPSG layers in a conventional furnace. The superior results may be noticeable in the filling of certain small-width, high aspect ratio gaps. The inventors have found that process 100 using a two-step deposition method allows filling of a gap having a width of 0.050 micron and an aspect ratio of 7:1. This is a substantial improvement from the one-step deposition method which could not fill 0.08-micron-wide gaps having a 6:1 aspect ratio.

In still further embodiments, the deposited FBPSG layers are subject to an optional treatment step 108 to improve the stability of the layers. Two different treatment steps 108 have been found to improve film stability. The main purpose of each is to prevent moisture absorption which can interact with the dopant and cause film instabilities. In the first, a nitride cap layer is formed over the FBPSG layers. The cap layer can be deposited from either a thermal or plasma process, but should be relatively thin (e.g., about 60Å) so that it does not adversely affect the reflow properties of the FBPSG layers. The second treatment subjects the deposited FBPSG film to a brief nitrogen (N₂) plasma in order to densify the film and form a very thin (approximately 20Å) SiOₓN_{y} film over the layers. In one specific embodiment, the N₂ plasma treatment forms a plasma from a 2000 sccm helium flow and a 500 sccm N₂ flow for 50 seconds at 1.5 torr and 400° C. The plasma is formed by application of 700 watts of RF energy at 450 KHz.

Having fully described several embodiments of the present invention, many other equivalent or alternative embodiments of the present invention will be apparent to those skilled in the art. These equivalents and alternatives are intended to be included within the scope of the present invention.

What is claimed is:

1. A method for depositing a layer over a substrate, said method comprising:
depositing a first halogen-doped borophosphosilicate glass (BPSG) layer over said substrate at a first pressure level; and
depositing a second halogen-doped BPSG layer over said first layer at a second pressure level, wherein said first pressure level is higher than said second pressure level.

2. The method of claim 1 wherein said first and second halogen-doped BPSG layers are fluorinated-BPSG (FBPSG) layers.

3. The method of claim 2 wherein said second FBPSG layer is deposited over an undoped silicon oxide layer.

4. The method of claim 3 wherein said silicon oxide layer is deposited from a plasma of oxygen and TEOS.

5. The method of claim 3 wherein said silicon oxide layer and said first and second FBPSG layers are deposited over a semiconductor substrate having transistors formed thereon.

6. The method of claim 5 wherein said first and second FBPSG layers are deposited over gaps having an aspect ratio of 6:1 or higher and a width of about 0.8 micron or less and wherein said reflow step enables said FBPSG layers to fill said gaps without the presence of voids.

7. A method of claim 2 wherein said first and second FBPSG layers are deposited in a cold-walled CVD chamber.

8. The method of claim 7 wherein said first and second FBPSG layers are deposited from a process gas comprising TEOS and TEFS.

9. The method of claim 1 wherein said first layer is deposited at a pressure greater than about 300 Torr and less than about 400 Torr.

10. The method of claim 9 wherein said first layer is an FBPSG layer.

11. The method of claim 10, wherein said first layer is deposited at about 300 Torr.

12. The method of claim 1 wherein said second layer is deposited at a pressure greater than about 150 Torr and less than about 200 Torr.

13. The method of claim 12 wherein said second layer is an FBPSG layer.

14. The method of claim 13, wherein said second layer is deposited at about 150 Torr.

15. The method of claim 1 further including processing said first and second halogen-doped BPSG layers using a rapid thermal pulse furnace.

16. The method of claim 15, wherein said processing of said first and second halogen-doped BPSG layers is carried out in a temperature greater than 900° C.

17. The method of claim 16, wherein said processing of said first and second halogen-doped BPSG layers is carried out for more than 20 seconds.

18. The method of claim 2 wherein said first FBPSG layer is deposited over a lining layer having a density less than about 2.5 g/cm³.

19. The method of claim 1 wherein said first pressure level is optimized to avoid a substantial boron concentration build-up at the interface between said first layer and said substrate, thereby preventing formation of undercuts in contact holes when said substrate is dipped in a solution after the contact etch.

20. A method for depositing a layer over a substrate, said method comprising:
depositing a first fluorine-doped borophosphosilicate glass (FBPSG) layer over said substrate at a first pressure level;
depositing a second FBPSG layer over said first layer at a second pressure level, wherein said first pressure level is higher than said second pressure level; and
reflowing said at least said second layer using a rapid thermal pulse furnace.

21. A method for depositing a layer over a substrate, said method comprising:
depositing a first halogen-doped borophosphosilicate glass (BPSG) layer over said substrate at a pressure between about 300 Torr and about 400 Torr using a process gas including about 17 wt. % O₃ at about 5000 sccm; and
depositing a second halogen-doped BPSG layer over said first layer at a pressure between about 150 Torr and about 200 Torr using a process gas including about 17 wt. % O₃ at about 5000 sccm.

22. A method for depositing a layer over a substrate, said method comprising:
depositing a first halogen-doped borophosphosilicate glass (BPSG) layer over said substrate at a first pressure level which is selected to provide said first layer with good film conformity; and
depositing a second halogen-doped BPSG layer over said first layer at a second pressure level which is selected to provide a relatively high deposition rate, wherein said first pressure level is higher than said second pressure level.

23. A method for depositing a premetal dielectric layer over a substrate, comprising:
depositing a first fluorinated-borophosphosilicate glass (FBPSG) layer over said substrate at a pressure of about 300 to 400 Torr using a process gas including tetraethoxysilane (TEOS), triethylborate (TEB), triethylfluorosilane (TEFS), triethylphosphate (TEPO), and about 17 wt. % O₃ at a deposition rate of about 1000 to 2000 Å/min, to form said first layer having 0.5 to 3 wt. % fluorine and good conformity; and
depositing a second FBPSG layer over said first layer at a pressure of about 150 to 200 Torr using a process gas including tetraethoxysilane (TEOS), triethylborate (TEB), triethylfluorosilane (TEFS), triethylphosphate (TEPO), and about 17 wt. % O₃ at a deposition rate of about 4000 to 5000 Å/min, to form said second FBPSG layer having 0.5 to 3 wt. % fluorine.

24. A method for depositing a premetal dielectric layer over a substrate, comprising:
depositing a first fluorinated-borophosphosilicate glass (FBPSG) layer over said substrate at a pressure of about 300 Torr using a process gas including tetraethoxysilane (TEOS), triethylborate (TEB), triethylfluorosilane (TEFS), triethylphosphate (TEPO), and about 17 wt. % O₃ at about 5000 sccm, for about 20 to 30 seconds at a deposition rate of about 1000 to 2000 Å/min, to form said first layer having 0.5 to 3 wt. % fluorine and good conformity;
depositing a second FBPSG layer over said first layer at a pressure of about 150 to 200 Torr using a process gas including tetraethoxysilane (TEOS), triethylborate (TEB), triethylfluorosilane (TEFS), triethylphosphate (TEPO), and about 17 wt. % O₃ at about 5000 sccm, for about 110-150 seconds at a deposition rate of about 4000 to 5000 Å/min, to form said second FBPSG layer having 0.5 to 3 wt. % fluorine; and
reflowing said first and second layers in a rapid thermal pulse furnace for 20 to 90 seconds at a temperature greater than 900° C. to minimize diffusion of fluorine atoms from said first and second layers.
